(19) United States
(12) Patent Application Publication
(10) Pub. No.: US 2005/0054156 A1
(43) Pub. Date: Mar. 10, 2005

(54) CAPACITOR AND FABRICATION METHOD USING ULTRA-HIGH VACUUM CVD OF SILICON NITRIDE

(75) Inventors: John Bruley, Poughkeepsie, NY (US); Kevin K. Chan, Staten Island, NY (US); Paul D. Kirsch, Fishkill, NY (US); Dae-Gyu Park, Wappingers Falls, NY (US)

Correspondence Address: HOFFMAN WARNICK & D'ALESSANDRO, LLC, 3 E-COMM SQUARE, ALBANY, NY, 12207, US

(73) Assignee: INTERNATIONAL BUSINESS MACHINES CORPORATION, Armonk, NY (US)

(21) Appl. No.: 10/605,128

(22) Filed: Sep. 10, 2003

(51) Int. Cl. H01L 21/8242

(52) U.S. Cl. 438/243

(57) ABSTRACT

A method of fabricating a capacitor including an ultra-high vacuum chemical vapor deposition (UHVCVD) step to generate a top-side barrier film layer including silicon nitride at monolayer quantities, and a capacitor so formed, are disclosed. The UHVCVD step allows silicon nitride to be deposited with monolayer level control, and is more successful at placing the nitrogen near the top surface independent of the base film thickness. The resulting capacitor exhibits thermal stability and meets leakage targets after, for example, an approximately 1050° C. thermal treatment. In addition, the UHVCVD nitride step allows for an in situ thermal clean and simpler process control because the reaction is thermally driven.

### BACKGROUND OF INVENTION

The present invention relates generally to capacitor fabrication, and more particularly to a capacitor fabrication method using ultra-high vacuum chemical vapor deposition of silicon nitride, and a capacitor so formed.

To maintain current process flows for embedded dynamic random access memory (DRAM) deep trench capacitors, it is necessary to enhance the thermal stability of high dielectric constant (“high-k”) materials such as aluminum oxide (Al₂O₃). In particular, conventional process integration is possible only if thermal stability to 1050° C. is demonstrated.

One proposed approach for providing greater thermal stability for high-k material has been to provide a top-side barrier film of, for example, silicon nitride (SiNₓ). While silicon nitride has conventionally been used as a bottom interfacial material for high-k material, inclusion of silicon nitride on top of a high-k dielectric is difficult because the substrate silicon (Si) is buried and cannot be used as a silicon source for interfacial layer formation. As an alternative, a number of approaches have been proposed for forming a top-side barrier film layer of nitrogen.

In one approach for generating a nitrogen barrier film layer, remote plasma nitridation (RPN) uses a remote plasma discharge through a nitrogen-inert gas mixture to form nitrogen (N) radicals and ions. In this case, most ions deactivate, leaving the radicals to diffuse into a separate reaction chamber and react at the dielectric surface, incorporating the nitrogen. Because the nitrogen radicals enter the chamber from the side (rather than top) a severe center-to-edge nitrogen profile exists. As a result, this approach suffers from a number of drawbacks. First, nitrogen dose near the wafer's edge can be much higher than in the center, e.g., approximately 50%. Second, nitrogen does not remain at the top surface; rather, nitrogen radicals have a finite diffusion length and some penetrate into the dielectric. Finally, RPN processing can be difficult to maintain for manufacturing purposes.

In another approach, reoxidation of metal nitrides such as aluminum-nitride (AlN) is implemented to form the top-side nitrogen layer. This approach, however, is disadvantageous because the placement of nitrogen will depend on the metal nitride film thickness and oxidant diffusivity. For a thick metal nitride film (e.g., approximately 50 Å) such as aluminum nitride (AlN) or silicon nitride (SiN), the reoxidation gas cannot penetrate the film to reach the underlying silicon (Si) substrate. As a result, the surface is reoxidized, leaving nitrogen near the substrate and oxygen (O) near the surface. Conversely, a very thin film (e.g., 15 Å) may allow oxidant to diffuse through to the silicon (Si) substrate forming interfacial SiOx.

In another approach, reactive sputtering processes utilize a mixture of nitrogen (N) and Argon (Ar) ions to sputter metal from a target to a surface. During this process, some nitrogen (N) is incorporated in the metal film, and the film may be oxidized in situ or ex situ. This approach, however, provides minimal control over nitrogen (N) placement. Furthermore, sputtering processes are not controllable with monolayer precision. More importantly, sputtering is not feasible for high aspect ratio features such as the embedded DRAM deep trench.

In addition to the drawbacks stated above, current approaches without top-side barrier films containing silicon and nitrogen exhibit increased leakage current. One possible explanation for the increased leakage current is that the transition of aluminum oxide (or other high-k dielectric material) from amorphous to polycrystalline during annealing, e.g., at 1050° C., opens diffusions (grain boundaries) to adjacent silicon (Si) atoms in the polysilicon electrode. The open diffusions may allow the penetrating silicon to perhaps compete with aluminum (Al) for oxygen (O) bonding partners near the aluminum oxide/polysilicon interface. This competition for oxygen (O) bonding partners leaves excess metallic species (possibly Al and Si) that are not fully coordinated with O atoms. The resulting oxygen vacancies may contribute to increased leakage current. A barrier layer of silicon nitride would slow silicon (Si) diffusion into the dielectric and therefore reduce the oxygen vacancy problem, but no implementable method for forming such a layer exists that can adequately control the thickness to the monolayer degree necessary. For example, use of low pressure chemical vapor deposition inadequately controls the thickness of the silicon nitride.

In view of the foregoing, there is a need in the art for a method of fabricating a capacitor with a top-side silicon nitride barrier film layer without the problems of the related art.

### SUMMARY OF INVENTION

This invention includes a method of fabricating a capacitor including an ultra-high vacuum chemical vapor deposition (UHVCVD) step to generate a top-side barrier film layer from silicon nitride at monolayer quantities, and a capacitor so formed. The UHVCVD step allows silicon nitride to be deposited with monolayer level control, and is more successful at placing the nitrogen near the top surface independent of the base film thickness. The resulting capacitor exhibits thermal stability and meets leakage targets after, for example, an approximately 1050° C. thermal treatment. In addition, the UHVCVD nitride step allows for an in situ thermal clean and simpler process control because the reaction is thermally driven.

A first aspect of the invention is directed to a method of fabricating a capacitor comprising: generating a first layer of silicon nitride upon a silicon substrate; depositing a high dielectric constant material layer; generating a second layer of silicon nitride by applying an ultra-high vacuum and depositing silicon nitride; and generating an electrode layer upon the second layer.

A second aspect of the invention is directed to a method of fabricating a capacitor comprising the steps of: conducting a rapid thermal nitridation in ammonia (NH3) to generate a first layer of silicon nitride upon a silicon substrate; depositing a layer including an aluminum oxide; applying an ultra-high vacuum; chemical vapor depositing (CVD) silicon nitride in the ultra-high vacuum; and generating an electrode layer upon the second layer.

A third aspect of the invention is directed to a capacitor comprising: a silicon substrate; a first layer of silicon nitride upon the silicon substrate; a high dielectric constant layer upon the first layer; a second layer of silicon nitride having monolayer quantities of the silicon nitride; and an electrode layer upon the second layer.

The foregoing and other features of the invention will be apparent from the following more particular description of embodiments of the invention.

### BRIEF DESCRIPTION OF DRAWINGS

The embodiments of this invention will be described in detail, with reference to the following figures, wherein like designations denote like elements, and wherein:

FIG. 1 shows a first step of a method of fabricating a capacitor.

FIG. 2 shows a second step of a method of fabricating a capacitor.

FIG. 3 shows a third step of a method of fabricating a capacitor.

FIG. 4 shows a fourth step of a method of fabricating a capacitor.

FIG. 5 shows a fifth step of a method of fabricating a capacitor.

FIG. 6 shows a capacitor fabricated according to the method of FIGS. 1-5.

FIG. 7 shows a comparison graph of leakage current versus bias.

FIG. 8 shows a comparison graph of leakage current versus anneal temperature.

FIG. 9 shows a comparison graph of capacitance versus bias.

FIG. 10 shows an electron energy loss spectra (EELS) of the capacitor of FIG. 6.

### DETAILED DESCRIPTION

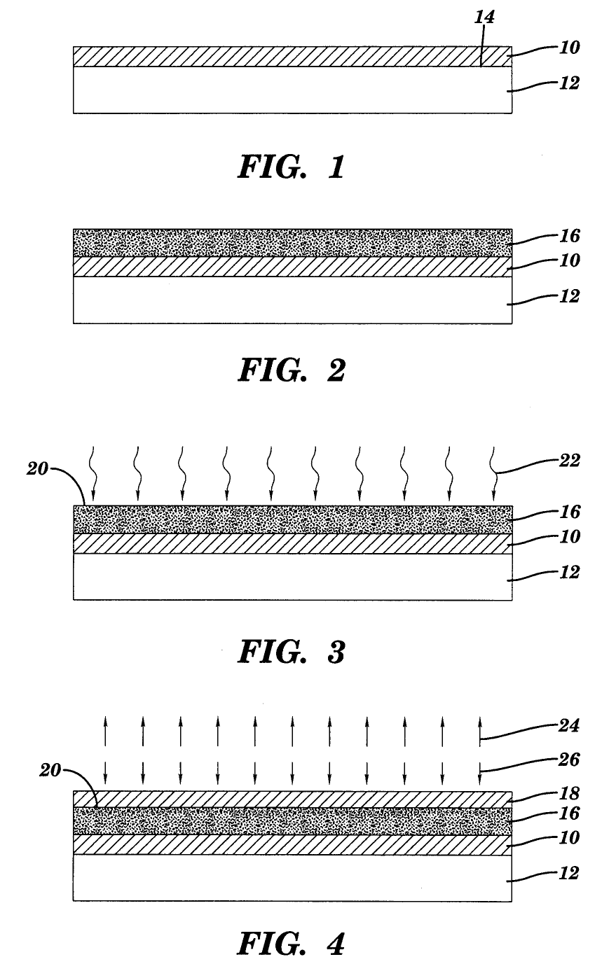

The invention includes a method of fabricating a capacitor and a capacitor so formed. With reference to the accompanying drawings, FIG. 1 shows a first step of the method, which includes generating a first layer 10 of silicon nitride upon a silicon substrate 12. Silicon substrate may be N++ doped, e.g., with arsenic. As a preparatory step, a surface 14 of silicon substrate 12 may be cleaned using a hydrofluoric acid (HF) last wet clean. In one embodiment, first layer 10 is generated by conducting a rapid thermal nitridation (RTN) in ammonia (NH₃). First layer 10 is, for example, no less than approximately 5 Å and no greater than approximately 15 Å.

FIG. 2 shows a next step of depositing a high dielectric constant (hereinafter “high-k”) material layer 16, e.g., k>3.9. In one embodiment, high-k material includes aluminum oxide (Al₂O₃). However, other high-k material 16 may include: hafnium oxide (HfO₂), zirconium oxide (ZrO₂), lanthanum oxide (LaO₂), silicates of the preceding, strontium titanate (STO), tantalum oxide (Ta₂O₅), a mixture dielectric of hafnium oxide (HfO₂) and aluminum oxide (Al₂O₃)(HfAlOₓ) and a mixture dielectric of zirconium oxide (ZrO₂) and aluminum oxide (Al₂O₃)(ZrAlOₓ). Deposition of high-k material layer 16 may occur, for example using atomic layer deposition (ALD). High-k material layer 16, in one embodiment, is no less than approximately 15 Å thick and no greater than approximately 50 Å thick.

Turning to FIGS. 3-4, a next step includes generating a second layer 18 (FIG. 4) of silicon nitride (SiN_{0.5-1.3})(hereinafter “nitride”). An optional preparatory step, shown in FIG. 3, includes cleaning a surface 20 of high-k material layer 16 in situ prior to depositing second layer 18. In one embodiment, as shown in FIG. 3, the cleaning step includes thermally cleaning 22 surface 20 of high-k material layer 16 in situ by heating to no less than approximately 600° C. and no greater than approximately 900° C., and preferably about 750° C. The thermal cleaning acts to desorb adsorbed water and organic contamination.

As shown in FIG. 4, the step of generating second layer 18 includes applying an ultra-high vacuum (UHV) 24 and depositing 26 nitride. The base pressure of the ultra-high vacuum, i.e., the pressure in the chamber prior to introduction of reactants, is at no less than approximately 10⁻¹¹ Torr and no greater than approximately 10⁻⁸ Torr, and preferably about 10⁻⁹ Torr. Once reactants are introduced, growth of monolayer quantities of nitride can occur in the microtorr to millitorr pressure ranges (i.e., at no less than approximately 10⁻⁶ Torr and no greater than approximately 10⁻² Torr), which provides a small growth rate and monolayer level process control. That is, the ultra-high vacuum is at no less than approximately 10⁻¹¹ Torr and no greater than approximately 10⁻⁸ Torr when idle and no less than approximately 10⁻⁶ Torr and no greater than approximately 10⁻² Torr during silicon nitride deposition.

The depositing step, in one embodiment, includes chemical vapor deposition (CVD) using silane (SiH₄) and ammonia (NH₃) as silicon (Si) and nitrogen (N) precursors. Which material, silane or ammonia, is introduced first may vary. When thermal cleaning 22 is provided, surface 20 of high-k material layer 16 has a temperature of no less than approximately 600° C. and no greater than approximately 900° C. during the step of generating the second layer, and preferably about 750° C., during the deposition. This temperature supplies the necessary thermal energy to break nitrogen-hydrogen (N—H) bonds and minimize the hydrogen (H) impurity in the deposited nitride film. The deposition time can be varied to increase the thickness of the deposited nitride of second layer 18. In one embodiment, second layer 18 includes nitride in monolayer quantities, i.e., no less than approximately 3 Å thick and no greater than approximately 8 Å thick. That is, deposition of second layer 18 can be controlled to include any number of monolayers (ML) in which each monolayer includes a single layer of silicon-nitrogen pairings.

In another embodiment, the depositing step may include radical assisted or a plasma assisted nitride deposition under UHV conditions such that the deposition can be conducted at lower temperatures than that provided with thermal cleaning 22. In addition, a radical assisted or plasma assisted deposition may also make the usage of the UHV deposition step applicable to a wider variety of high-k dielectrics such as hafnium oxide (HfO₂), zirconium oxide (ZrO₂), lanthanum oxide (LaO₂), silicates of the preceding, strontium titanate (STO), tantalum oxide (Ta₂O₅), a mixture dielectric of hafnium oxide (HfO₂) and aluminum oxide (Al₂O₃)(HfAlOₓ) and a mixture dielectric of zirconium oxide (ZrO₂) and aluminum oxide (Al₂O₃)(ZrAlOₓ).

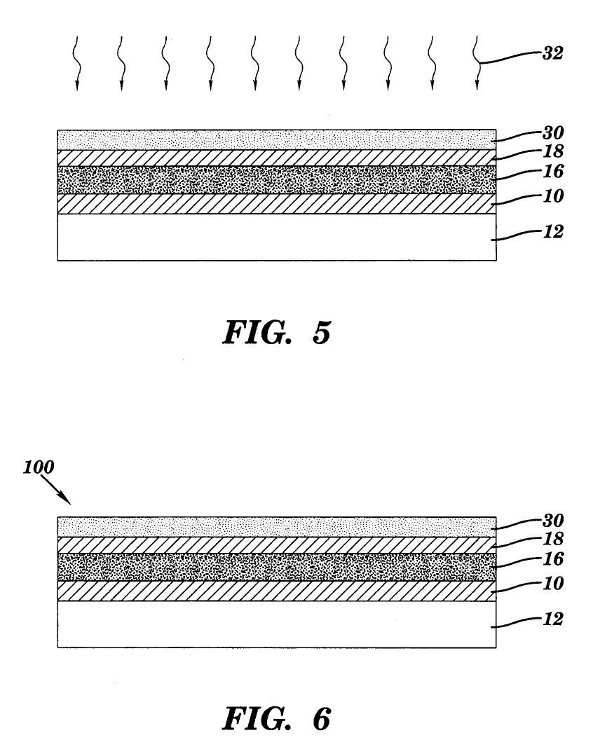

As a next step, shown in FIG. 5, the method includes generating an electrode layer 30 upon second layer 18, e.g., of polysilicon. Electrode layer 30 (e.g., N++ doped with arsenic) may be generated by any now known or later developed manner. Finally, a thermal anneal 32 may be conducted to activate dopants. Since second layer 18 includes nitride in monolayer quantities, the generation of oxygen vacancies at the dielectric interface is prevented by the existence of silicon nitride. This is in contrast to prior art techniques that generate a nitrogen-only top-side layer that only includes aluminum, oxygen and nitrogen. As a result of the UHVCVD of nitride second layer 18, the leakage current is reduced as will be described further below.

FIG. 6 shows a capacitor 100 fabricated according to the above method using aluminum oxide as the high-k material. Capacitor 100 includes a silicon substrate 12, a first (bottom-side) layer 10 of silicon nitride upon silicon substrate 12; a high-k material layer 16 upon first layer 10; a second (top-side) layer 18 of nitride having monolayer quantities of nitride; and an electrode layer 30 upon the second layer.

Capacitor 100 fabricated according to the above method using UHVCVD of nitride exhibits a 50-times reduction in leakage current from the addition of top-side layer 18 compared to conventional aluminum oxide capacitors. This result was determined after a 1050° C., 30 second anneal. This result is significant because it allows aluminum oxide integration with conventional fabrication flows realizing high-k capacitance enhancement. Because top-side layer 18 (FIG. 6) is only monolayers thick, and has a permittivity approximately twice that of silicon dioxide (SiO₂), a capacitance equivalent thickness (CET) was observed to increase just 1.2 Å. As a result, this minimal increase in CET may allow use of this scalable solution to multiple technology sizes, e.g., 90 nm and 65 nm.

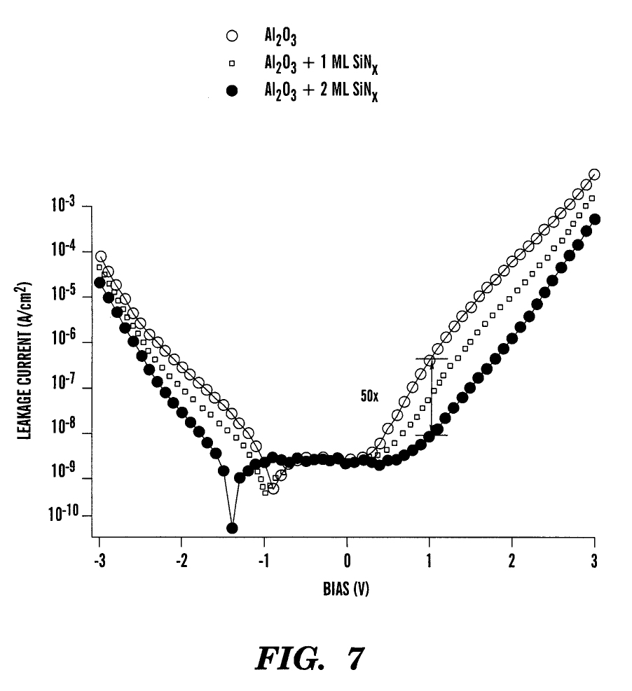

FIG. 7 shows a comparison graph of leakage current (A/cm ²) versus bias in volts (V) for a capacitor 100. FIG. 7 shows the effect of top-side layer 18 on leakage current after a 1050° C., 30 second anneal. In this sample, capacitors were prepared with 0, 1 and 2 monolayers (ML) of nitride, then thermally stressed and electrically tested. This data shows a 25-time reduction in leakage current with each additional monolayer of nitride at a bias of 1 volt (V). The addition of two monolayers of nitride reduces leakage 50-times versus a structure with no nitride, i.e., 0 ML.

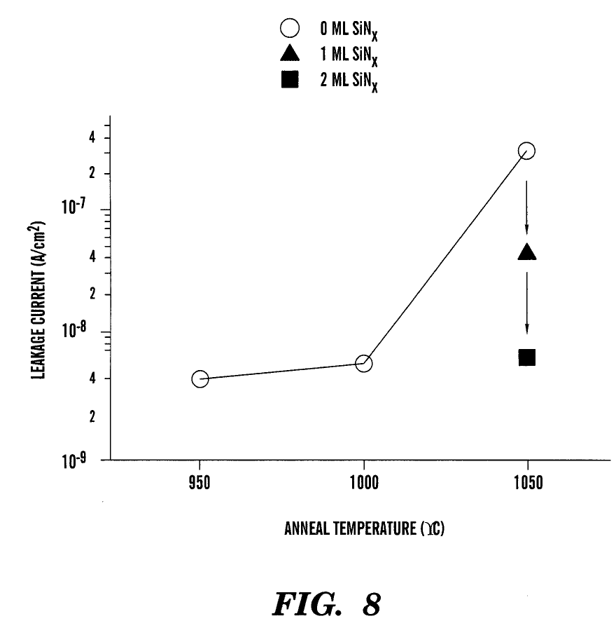

FIG. 8 shows a comparison graph of leakage current (A/cm ²) versus anneal temperature (° C.) for wafers that were stressed to different temperatures. The open circles show that leakage increases quickly as the system is stressed beyond 1000° C. However, the solid symbols show that a top-side layer 18 reduces leakage for the most aggressive thermal budget to values equivalent to that of the 1000° C., ten second thermal budget.

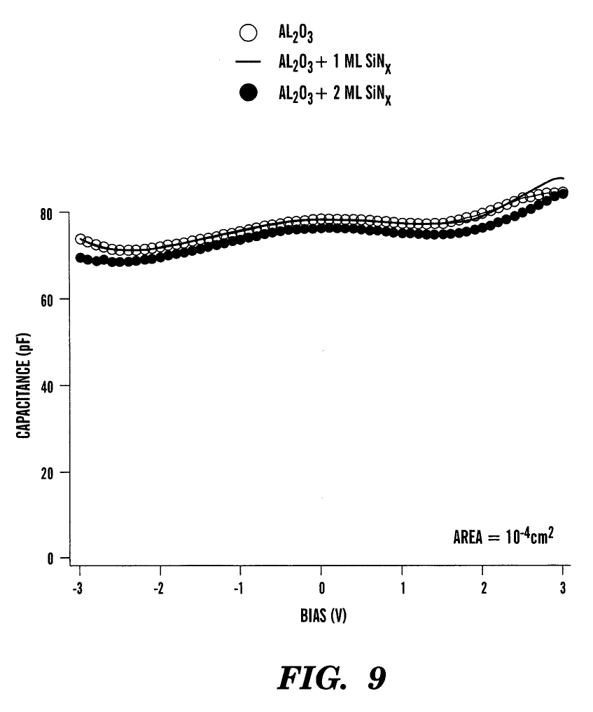

FIG. 9 shows a comparison graph of capacitance (pF) versus bias (V) (C-V) curves for the different second (top-side) layer schemes. The three curves represent aluminum oxide capacitors, each with a different nitride layer barrier scheme. The nitride layer is different in each case: 0 ML—open circles; 1 ML—solid line; and 2 ML—dark circles. The capacitance value at 0 V is similar for each of the three aluminum oxide capacitors, regardless of the thickness of the nitride layer. Capacitance equivalent thicknesses (CET) were calculated to be approximately: 44.1 Å, 44.1 Å and 45.3 Å for the cases with 0, 1, and 2 ML top-side layer, respectively. Nonetheless, FIG. 7 shows that leakage current decreases approximately 50-times with 2 ML of nitride, which is likely a result of the combined effect of nitride barrier properties, chemical inertness and increased CET, rather than the CET increase alone. In particular, because nitride has a permitivity approximately twice that of silicon dioxide (SiO₂), the physical thickness increase in capacitor 100 (FIG. 6) may be as large as 2.4 Å, which is not enough to exclusively explain the 50-times leakage current reduction. (For silicon dioxide, a thickness increase of approximately 3.8 Å would be needed to reduce leakage 50-times). This discrepancy supports the argument that nitride reduces leakage current because of its barrier properties and chemical inertness.

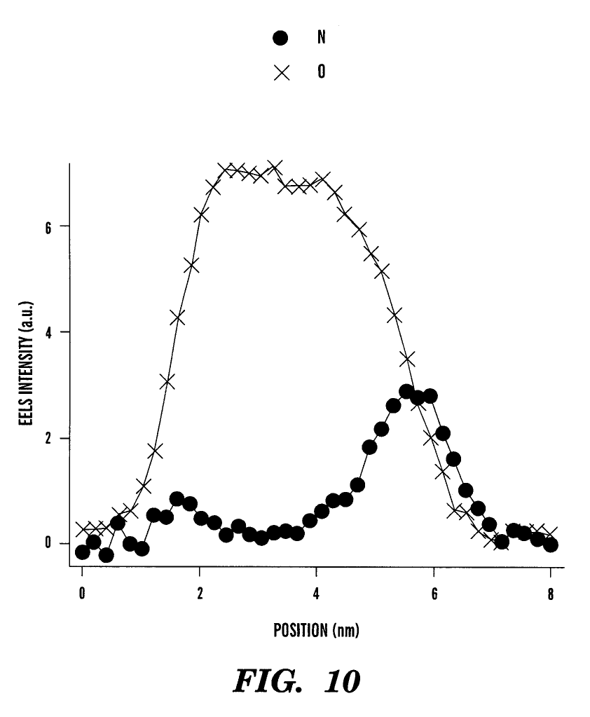

Chemical and physical characterization using electron energy loss spectroscopy (EELS) is shown in FIG. 10. The EELS chemical linescan shows nitrogen (N) intensity from top-side layer 18 (FIG. 6) at the top interface of the layer's stack. Nitrogen (N) intensity on the bottom (near 6 nm) results from first layer 12 (FIG. 6) surface preparation and the nitrogen intensity at the top interface (near 1.5 nm) is evidence of the deposited monolayers of UHVCVD nitride.

While this invention has been described in conjunction with the specific embodiments outlined above, it is evident that many alternatives, modifications and variations will be apparent to those skilled in the art. Accordingly, the embodiments of the invention as set forth above are intended to be illustrative, not limiting. Various changes may be made without departing from the spirit and scope of the invention as defined in the following claims.

1-12. (Cancelled).

13. A method of fabricating a capacitor, the method comprising the steps of:
generating a first layer of silicon nitride upon a silicon substrate;
depositing a layer including an aluminum oxide;
cleaning the layer including aluminum oxide in situ;
applying an ultra-high vacuum;
chemical vapor depositing (CVD) silicon nitride in the ultra-high vacuum to generate a second layer of silicon nitride; and
generating an electrode layer upon the second layer.

14. The method of claim 13, further comprising the step of cleaning the silicon substrate in hydrofluoric acid (HF) prior to generating the first layer.

15. (Cancelled)

16. The method of claim 13, wherein the layer including aluminum oxide has a surface temperature of no less than approximately 600° C. and no greater than approximately 900° C. during the step of generating the second layer.

17. The method of claim 13, wherein the ultra-high vacuum is at no less than approximately 10⁻¹¹ Torr and no greater than approximately 10⁻⁸ Torr when idle and no less than approximately 10⁻⁶ Torr and no greater than approximately 10⁻² Torr during silicon nitride deposition.

18. The method of claim 13, wherein the step of CVD uses silane (SiH₄) and ammonia (NH₃) as silicon (Si) and nitrogen (N) precursors.

19. The method of claim 13, further comprising the step of conducting a thermal anneal.

20. (Cancelled).

21. The method of claim 13, wherein the first layer is no less than approximately 5 Å and no greater than approximately 15 Å.

22. The method of claim 13, wherein the layer including aluminum oxide is no less than approximately 15 Å thick and no greater than approximately 50 Å thick.

23. The method of claim 13, wherein the second layer is no less than approximately 3 Å thick and no greater than approximately 8 Å thick.

24. The method of claim 13, wherein the step of generating the first layer includes conducting a rapid thermal nitridation in ammonia (NH₃).
